(19) United States
(12) Patent Application Publication
(10) Pub. No.: US 2023/0339517 A1
(43) Pub. Date: Oct. 26, 2023

(54) AUTONOMOUS DRIVING EVALUATION SYSTEM

(71) Applicant: GM Global Technology Operations LLC, Detroit, MI (US)

(72) Inventors: Syed Bilal Mehdi, Southfield, MI (US); Marcus James Huber, Saline, MI (US); Sayyed Rouhollah Jafari Tafti, Troy, MI (US); Jeremy A. Salinger, Southfield, MI (US)

(21) Appl. No.: 17/726,785

(22) Filed: Apr. 22, 2022

(51) Int. Cl. B60W 60/00; G07C 5/02; G06F 30/20

(52) U.S. Cl. CPC B60W 60/0053; G07C 5/02; G06F 30/20; B60W 2554/406; B60W 2555/60

(57) ABSTRACT

A system comprises a computer including a processor and a memory. The memory includes instructions such that the processor is programmed to: execute an autonomous vehicle algorithm simulating vehicle operations within a simulated environment. The simulated environment represents a plurality of driving situations. The memory also includes instructions such that the processor is programmed to: determine a challenge rating for the driving situation, determine an autonomous vehicle performance assessment score corresponding to the simulated environment, compare the autonomous vehicle performance assessment score with a human driving score corresponding to the simulated environment, and generate a performance profile based on the comparison. In some implementations, a vehicle computer can determine a challenge rating and generate at least one of a driver takeover recommendation or an alert indicating a presence of a fault based on a comparison of vehicle performance with the challenge rating.

### INTRODUCTION

The present disclosure relates to an autonomous vehicle performance assessment system.

An autonomous vehicle is a vehicle that is capable of sensing its environment and navigating with little or no user input. It does so by using sensing devices such as radar, lidar, image sensors, and the like. Autonomous vehicles further use information from global positioning systems (GPS) technology, navigation systems, vehicle-to-vehicle communication, vehicle-to-infrastructure technology, and/or drive-by-wire systems to navigate the vehicle.

### SUMMARY

A system comprises a computer including a processor and a memory. The memory includes instructions such that the processor is programmed to: execute an autonomous vehicle algorithm simulating vehicle operations within a simulated environment. The simulated environment represents a plurality of driving situations. The memory also includes instructions such that the processor is programmed to: determine a challenge rating corresponding to the simulated environment, determine an autonomous vehicle performance assessment score corresponding to the simulated environment, compare the autonomous vehicle performance assessment score with a human driving score corresponding to the simulated environment, and generate a plurality of performance profiles based on the comparison.

In other features, the processor is further programmed to generate the simulated environment based on a measure M, wherein the measure M comprises a set of varying conditions for a driving scenario under which autonomous vehicle driving performance is evaluated.

In other features, the measure M is based on at least one of a complexity of a driving situation, a congestion of a driving situation, or chaos of a driving situation.

In other features, the complexity of the driving situation represents a number of multiple lane changes that are to occur within a defined roadway segment.

In other features, the congestion of the driving situation represents other vehicles traveling at a relatively lower rate of speed with respect to a posted speed limit.

In other features, the chaos of the driving situation represents a number of lane changes by other vehicles proximate to an ego-vehicle.

In other features, the processor is further programmed to generate simulated sensor data representing the simulated environment.

In other features, the processor is further programmed to determine a challenge rating for each generated driving situation within the simulated environment.

In other features, the processor is further programmed to determine the challenge rating for each generated driving situation within the simulated environment during a descriptive mode of operation.

A method includes executing an autonomous vehicle algorithm simulating vehicle operations within a simulated environment. The simulated environment represents a plurality of driving situations. The method also includes determining a challenge rating corresponding to the simulated environment, determining an autonomous vehicle performance assessment score corresponding to the simulated environment, comparing the autonomous vehicle assessment score with a human driving score corresponding to the simulated environment, and generating a plurality of performance profile based on the comparison.

In other features, the method includes generating the simulated environment based on a measure M, wherein the measure M comprises a set of varying conditions for a driving scenario under which autonomous vehicle driving performance is evaluated.

In other features, the measure M is based on at least one of a complexity of a driving situation, a congestion of a driving situation, or chaos of a driving situation.

In other features, the complexity of the driving situation represents a number of multiple lane changes that are to occur within a defined roadway segment.

In other features, the congestion of the driving situation represents other vehicles traveling at a relatively lower rate of speed with respect to a posted speed limit.

In other features, the chaos of the driving situation represents a number of lane changes by other vehicles proximate to an ego-vehicle.

In other features, method includes generating simulated sensor data representing the simulated environment.

In other features, the method includes determining a challenge rating for each generated driving situation within the simulated environment.

In other features, the method includes determining the challenge rating for each generated driving situation within the simulated environment during at least one of a descriptive mode of operation or a prescriptive mode of operation.

A vehicle includes a computer, and the computer includes a processor and a memory. The memory includes instructions such that the processor is programmed to: determine a challenge rating based on a defined measure M using sensor data from one or more sensors and generate at least one of a driver takeover recommendation or an alert indicating a presence of a fault based on a comparison of vehicle performance with the challenge rating.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a block diagram of an example system including a vehicle;

FIG. 2 is a block diagram of an example server within the system;

FIG. 3 is a block diagram of an example computing device;

FIG. 4 is a flow diagram illustrating an example process for benchmarking driving operations within a simulated driving environment during a prescriptive mode of operation;

FIG. 5 is a flow diagram illustrating an example process for benchmarking driving operations within a simulated driving environment during a descriptive mode of operation;

FIG. 6 is a flow diagram illustrating an example process for determining whether to generate a driver takeover recommendation; and

FIG. 7 is a flow diagram illustrating an example process for detecting a presence of a fault.

### DETAILED DESCRIPTION

The following description is merely exemplary in nature and is not intended to limit the present disclosure, application, or uses.

A challenge in developing autonomous vehicle algorithms is validating performance over miles of road testing. In some instances, simulation tools, including gaming engines, can be used to manually generate scenarios, collect simulated sensor data, and validate autonomous vehicle algorithm performance.

Within the present disclosure, a storage device can be loaded with a list of different feature combinations for a scenario. Feature combinations for a scenario can include vehicle poses, environmental factors, and other aspects of a simulation, such as, of a feature for L2-L5 automation. Based on a measure M, a selection of different simulated driving environments can be selected to represent one or more driving conditions. Sensor data and ground truth can be generated for each different driving condition, and the sensor data for each different driving condition is provided to an autonomous vehicle algorithm.

For each different driving condition, the algorithm determines metrics for the scenario, such as, a binary metric, i.e., if a scenario succeeded or failed, a non-binary metric, or other custom defined metric. The algorithm outputs each driving condition along with metrics, such as, if the algorithm passed or failed. These metrics can be compared with human driving metrics that represent metrics of whether a human driver passed or failed for each driving condition.

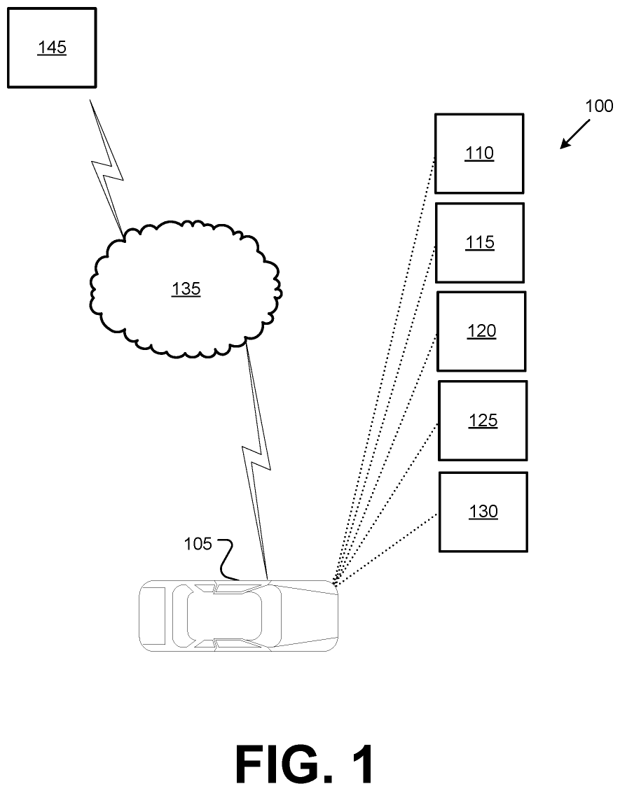

FIG. 1 is a block diagram of an example vehicle system 100. The system 100 includes a vehicle 105, which is a land vehicle such as a car, truck, etc. The vehicle 105 includes a computer 110, vehicle sensors 115, actuators 120 to actuate various vehicle components 125, and a vehicle communications module 130. Via a network 135, the communications module 130 allows the computer 110 to communicate with a server 145.

The computer 110 may operate a vehicle 105 in an autonomous, a semi-autonomous mode, or a non-autonomous (manual) mode. For purposes of this disclosure, an autonomous mode is defined as one in which each of vehicle 105 propulsion, braking, and steering are controlled by the computer 110; in a semi-autonomous mode the computer 110 controls one or two of vehicles 105 propulsion, braking, and steering; in a non-autonomous mode a human operator controls each of vehicle 105 propulsion, braking, and steering.

The computer 110 may include programming to operate one or more of vehicle 105 brakes, propulsion (e.g., control of acceleration in the vehicle by controlling one or more of an internal combustion engine, electric motor, hybrid engine, etc.), steering, climate control, interior and/or exterior lights, etc., as well as to determine whether and when the computer 110, as opposed to a human operator, is to control such operations. Additionally, the computer 110 may be programmed to determine whether and when a human operator is to control such operations.

The computer 110 may include or be communicatively coupled to, e.g., via the vehicle 105 communications module 130 as described further below, more than one processor, e.g., included in electronic controller units (ECUs) or the like included in the vehicle 105 for monitoring and/or controlling various vehicle components 125, e.g., a powertrain controller, a brake controller, a steering controller, etc. Further, the computer 110 may communicate, via the vehicle 105 communications module 130, with a navigation system that uses the Global Position System (GPS). As an example, the computer 110 may request and receive location data of the vehicle 105. The location data may be in a known form, e.g., geo-coordinates (latitudinal and longitudinal coordinates).

The computer 110 is generally arranged for communications on the vehicle 105 communications module 130 and also with a vehicle 105 internal wired and/or wireless network, e.g., a bus or the like in the vehicle 105 such as a controller area network (CAN) or the like, and/or other wired and/or wireless mechanisms.

Via the vehicle 105 communications network, the computer 110 may transmit messages to various devices in the vehicle 105 and/or receive messages from the various devices, e.g., vehicle sensors 115, actuators 120, vehicle components 125, a human machine interface (HMI), etc. Alternatively or additionally, in cases where the computer 110 actually comprises a plurality of devices, the vehicle 105 communications network may be used for communications between devices represented as the computer 110 in this disclosure. Further, as mentioned below, various controllers and/or vehicle sensors 115 may provide data to the computer 110. The vehicle 105 communications network can include one or more gateway modules that provide interoperability between various networks and devices within the vehicle 105, such as protocol translators, impedance matchers, rate converters, and the like.

Vehicle sensors 115 may include a variety of devices such as are known to provide data to the computer 110. For example, the vehicle sensors 115 may include Light Detection and Ranging (lidar) sensor(s) 115, etc., disposed on a top of the vehicle 105, behind a vehicle 105 front windshield, around the vehicle 105, etc., that provide relative locations, sizes, and shapes of objects and/or conditions surrounding the vehicle 105. As another example, one or more radar sensors 115 fixed to vehicle 105 bumpers may provide data to provide and range velocity of objects (possibly including second vehicles 106), etc., relative to the location of the vehicle 105. The vehicle sensors 115 may further include camera sensor(s) 115, e.g., front view, side view, rear view, etc., providing images from a field of view inside and/or outside the vehicle 105.

The vehicle 105 actuators 120 are implemented via circuits, chips, motors, or other electronic and or mechanical components that can actuate various vehicle subsystems in accordance with appropriate control signals as is known. The actuators 120 may be used to control components 125, including braking, acceleration, and steering of a vehicle 105.

In the context of the present disclosure, a vehicle component 125 is one or more hardware components adapted to perform a mechanical or electro-mechanical function or operation—such as moving the vehicle 105, slowing or stopping the vehicle 105, steering the vehicle 105, etc. Non-limiting examples of components 125 include a propulsion component (that includes, e.g., an internal combustion engine and/or an electric motor, etc.), a transmission component, a steering component (e.g., that may include one or more of a steering wheel, a steering rack, etc.), a brake component (as described below), a park assist component, an adaptive cruise control component, an adaptive steering component, a movable seat, etc.

In addition, the computer 110 may be configured for communicating via a vehicle-to-vehicle communication module or interface 130 with devices outside of the vehicle 105, e.g., through a vehicle to vehicle (V2V) or vehicle-to-infrastructure (V2X) wireless communications to another vehicle, to (typically via the network 135) a remote server 145. The module 130 could include one or more mechanisms by which the computer 110 may communicate, including any desired combination of wireless (e.g., cellular, wireless, satellite, microwave and radio frequency) communication mechanisms and any desired network topology (or topologies when a plurality of communication mechanisms are utilized). Exemplary communications provided via the module 130 include cellular, Bluetooth®, IEEE 802.11, dedicated short-range communications (DSRC), and/or wide area networks (WAN), including the Internet, providing data communication services.

The network 135 can be one or more of various wired or wireless communication mechanisms, including any desired combination of wired (e.g., cable and fiber) and/or wireless (e.g., cellular, wireless, satellite, microwave, and radio frequency) communication mechanisms and any desired network topology (or topologies when multiple communication mechanisms are utilized). Exemplary communication networks include wireless communication networks (e.g., using Bluetooth, Bluetooth Low Energy (BLE), IEEE 802.11, vehicle-to-vehicle (V2V) such as Dedicated Short-Range Communications (DSRC), etc.), local area networks (LAN) and/or wide area networks (WAN), including the Internet, providing data communication services.

A computer 110 can receive and analyze data from sensors 115 substantially continuously, periodically, and/or when instructed by a server 145, etc. Further, object classification or identification techniques can be used, e.g., in a computer 110 based on lidar sensor 115, camera sensor 115, etc., data, to identify a type of object, e.g., vehicle, person, rock, pothole, bicycle, motorcycle, etc., as well as physical features of objects.

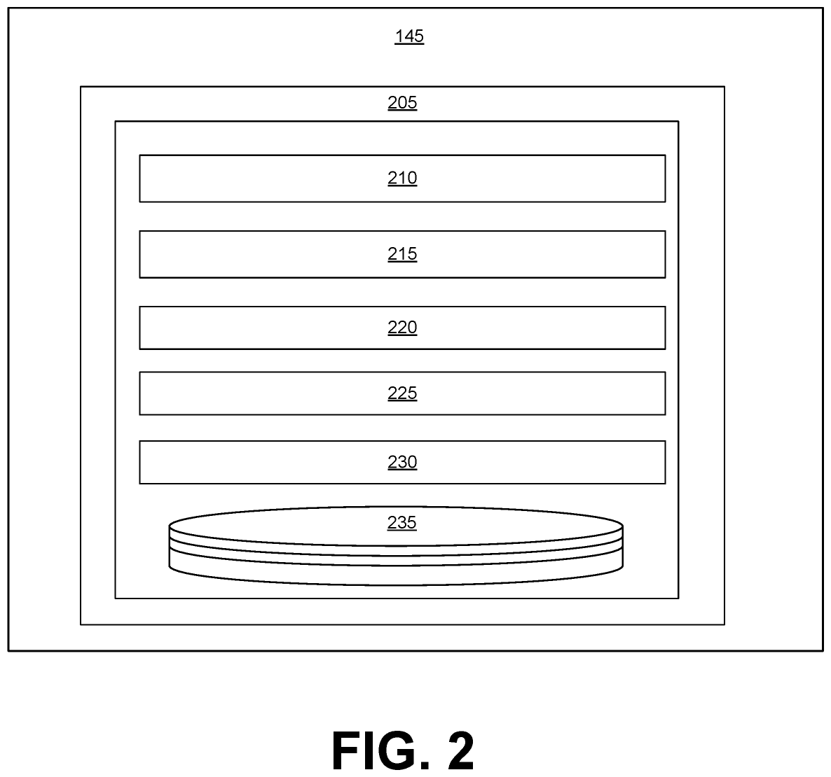

FIG. 2 illustrates an example server 145 that includes a performance evaluation system 205. As shown, the performance evaluation system 205 may include an autonomous vehicle control module 210, a challenge generation module 215, a driving challenge rating module 220, a performance assessment module 225, a profile generation module 230, and a storage module 235.

The autonomous vehicle control module 210 can comprise the autonomous vehicle software stack. For example, the autonomous vehicle control module 210 can include one or more software modules that determines vehicle localization, i.e., determining a location of a vehicle in a map, manages vehicle perception, i.e., determining information about objects around the vehicle, and/or provides instructions/controls for controlling the vehicle 105.

The challenge generation module 215 generates one or more simulated driving situations, e.g., driving environments, based on a defined measure M. The measure M can represent a set of varying conditions for a driving scenario under which autonomous vehicle driving performance is evaluated.

More specifically, the measure M can represent values that account for a complexity of a driving situation, a congestion of a driving situation, or chaos of a driving situation. Non-limiting examples of complexity can comprise number of multiple lane changes that are to occur within a defined roadway segment, road structure and the ego-vehicle's, e.g., vehicle 105, route plan causing the vehicle 105 to perform lane changes within a short distance/time, road structure forcing the ego-vehicle to accelerate while merging, the ego-vehicle needing to take into account cross-traffic, uncontrolled intersections, curving/winding roadways that involve “hairpin” curves, and/or roadways having significant elevation changes.

Examples of congestion can comprise other vehicles traveling at a relatively lower rate of speed with respect to a posted speed limit, a queue of stopped vehicles forming, and/or relatively small lead-time distance between vehicles.

Examples of chaos can comprise frequent lane changes by other vehicles proximate to the ego-vehicle, relatively high-speed variation of vehicles proximate to the ego-vehicle, other vehicles not following the center lane, other vehicles not obeying lane markers, other vehicles involved in double parking, and/or pedestrians and/or animals crossing the street.

The challenge generation module 215 can receive the measure M and generate a simulated driving situation based on the measure M. For example, the challenge generation module 215 generates a scenario file, i.e., JSON file, text file, etc. that includes variables for defining a simulated scenario. The scenario file can be stored in the storage module 235. For instance, the challenge generation module 215 can generate a driving challenge based on simulated weather conditions, i.e., icy road conditions, objects obscuring lane markings, and/or windy conditions, based on ethical complexities, i.e., whether the ego-vehicle yields to another vehicle that does not have the right-of-way and/or perform a vehicle maneuver due to detected pedestrian, based on mapping and localization complexities, i.e., inaccurate or sparsely detailed maps and/or GPS unavailability, based on a complete or partial failure of one or more vehicle 105 systems, based on low visibility due to weather conditions, based on traffic behavior variations due to weather and/or road conditions, and/or modified traffic patterns due to accidents.

Further, as discussed in greater detail herein, the challenge generation module 215 uses the scenario file to generate a simulated environment. For example, using the scenario file, the challenge generation module 215 generates a simulation in a virtual environment. As such, the challenge generation module 215 can generate sensor data, such as video data from a camera, point cloud data from lidars, detections from radar, audio, or any other kinds of simulated sensor data. The virtual environment can include one or more generated driving situations based on the measure M.

During a prescriptive mode of operation, the driving challenge rating module 220 computes driving challenge ratings for each generated driving situations prior to evaluating the autonomous vehicle performance in simulated driving situations. The challenge rating can comprise a numerical value indicative of a level of difficulty based on the measure M, such as simulated traffic congestion, simulated traffic chaos, simulated road complexity, etc.

The performance assessment module 225 monitors the outcome, i.e., assess, of executing autonomous vehicle algorithm for each driving situation and outputs data including each driving situation and an indication if driving operations selected the autonomous vehicle algorithm based on the driving situation passed or failed.

Further, the performance assessment module 225 can generate autonomous vehicle metrics, e.g., statistics, about the autonomous vehicle algorithm, such as an indication of how many times each simulated driving condition was associated with a failure of the autonomous vehicle algorithm, how many times each simulated driving condition was associated with a success of the autonomous vehicle algorithm, and the like. Based on the data, the performance assessment module 225 can generate a single scalar score that represents an aggregation of the assessment factors.

The autonomous vehicle metrics with data representing human driving metrics corresponding to a human driver driving through comparable driving situations can be compared. More specifically, a human driver drives through the same simulated environment, and the performance assessment module 225 generates a score similar to the techniques described above with respect to the selected autonomous vehicle algorithm. The comparison between scores can provide a good evaluation metric on how the autonomous vehicle is performing against a gold standard of an expert human driver.

During a descriptive mode of operation, the driving challenge rating module 220 determines the driving challenge ratings during the evaluation of the autonomous vehicle performance in the simulated driving situations. More specifically, as described above, the driving challenge ratings are determined prior to the performance evaluation phase during the prescriptive mode of operation, and the driving challenge ratings are determined contemporaneously with the performance evaluation step during the descriptive mode of operation.

The profile generation module 230 can generate one or more profiles based on a comparison of the autonomous vehicle assessment score and the human driving score and/or a comparison of the driving challenge ratings. The one or more profiles can comprise driver takeover recommendation profiles that can be used by the computer 110 to determine when to generate a driver takeover recommendation.

As described above, the autonomous vehicle and the human driving scores represent numerical values indicative of how a driving operation was performed in the driving situation. For example, the autonomous vehicle algorithm may have failed within a particular simulated environment due to the complexity of the driving situation, the congestion of the driving environment, and/or the chaos of the driving environment. The profiles can be used by the computer 110 for challenge assessment and performance assessment purposes as discussed herein.

In an example implementation, the computer 110 can use the profiles to determine whether a driver should take over control of the vehicle 105. More specifically, the computer 110 compares the one or more challenge ratings stored within the profile. If the measure M exceeds the challenge rating(s), the computer 110 generates a recommendation that a human driver takeover control of the vehicle 105. Within this context, the measure M can be determined based on the detected sensor data. For instance, the computer 110 can use a lookup table that relates sensor data to a corresponding measure M.

In some implementations, the computer 110 can detect and report possible faults within the vehicle 105. More specifically, the computer 110 compares the measure M to the one or more challenge ratings stored within the profile. The computer 110 also analyzes a performance of the selected autonomous vehicle driving algorithm within the driving environment, i.e., environment corresponding to measure M. The computer 110 can then determine whether the performance is lower than expected for a given challenge, the computer 110 can log the data, transmit the data with a vehicle manufacturer, and/or generate an alert to notify the vehicle 105 operator. For instance, the alert may indicate that the vehicle operator should schedule a dealership visit.

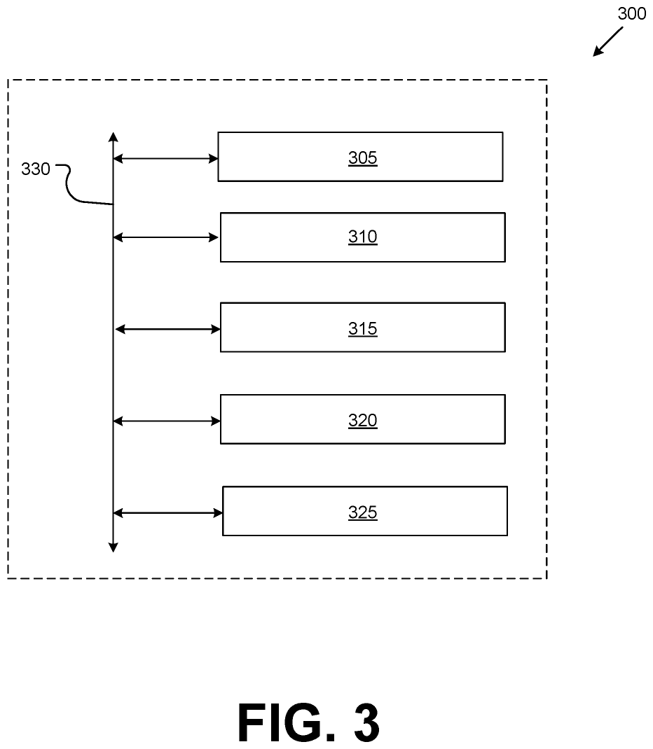

FIG. 3 illustrates an example computing device 300 i.e., computer 110 and/or server(s)145 that may be configured to perform one or more of the processes described herein. As shown, the computing device can comprise a processor 305, memory 310, a storage device 315, an I/O interface 320, and a communication interface 325. Furthermore, the computing device 300 can include an input device such as a touchscreen, mouse, keyboard, etc. In certain implementations, the computing device 300 can include fewer or more components than those shown in FIG. 3.

In particular implementations, processor(s) 305 includes hardware for executing instructions, such as those making up a computer program. As an example, and not by way of limitation, to execute instructions, processor(s) 305 may retrieve (or fetch) the instructions from an internal register, an internal cache, memory 310, or a storage device 315 and decode and execute them.

The computing device 300 includes memory 310, which is coupled to the processor(s) 305. The memory 310 may be used for storing data, metadata, and programs for execution by the processor(s). The memory 310 may include one or more of volatile and non-volatile memories, such as Random-Access Memory (“RAM”), Read Only Memory (“ROM”), a solid-state disk (“SSD”), Flash, Phase Change Memory (“PCM”), or other types of data storage. The memory 310 may be internal or distributed memory.

The computing device 300 includes a storage device 315 includes storage for storing data or instructions. As an example, and not by way of limitation, storage device 315 can comprise a non-transitory storage medium described above. The storage device 315 may include a hard disk drive (HDD), flash memory, a Universal Serial Bus (USB) drive or a combination of these or other storage devices.

The computing device 300 also includes one or more input or output (“I/O”) devices/interfaces 320, which are provided to allow a user to provide input to (such as user strokes), receive output from, and otherwise transfer data to and from the computing device 300. These I/O devices/interfaces 320 may include a mouse, keypad or a keyboard, a touch screen, camera, optical scanner, network interface, modem, other known I/O devices or a combination of such I/O devices/interfaces 320. The touch screen may be activated with a writing device or a finger.

The I/O devices/interfaces 320 may include one or more devices for presenting output to a user, including, but not limited to, a graphics engine, a display (e.g., a display screen), one or more output drivers (e.g., display drivers), one or more audio speakers, and one or more audio drivers. In certain implementations, devices/interfaces 320 is configured to provide graphical data to a display for presentation to a user. The graphical data may be representative of one or more graphical user interfaces and/or any other graphical content as may serve a particular implementation.

The computing device 300 can further include a communication interface 325. The communication interface 325 can include hardware, software, or both. The communication interface 325 can provide one or more interfaces for communication (such as, for example, packet-based communication) between the computing device and one or more other computing devices 300 or one or more networks. As an example, and not by way of limitation, communication interface 325 may include a network interface controller (NIC) or network adapter for communicating with an Ethernet or other wire-based network or a wireless NIC (WNIC) or wireless adapter for communicating with a wireless network, such as a WI-FI. The computing device 300 can further include a bus 330. The bus 330 can comprise hardware, software, or both that couples components of computing device 300 to each other.

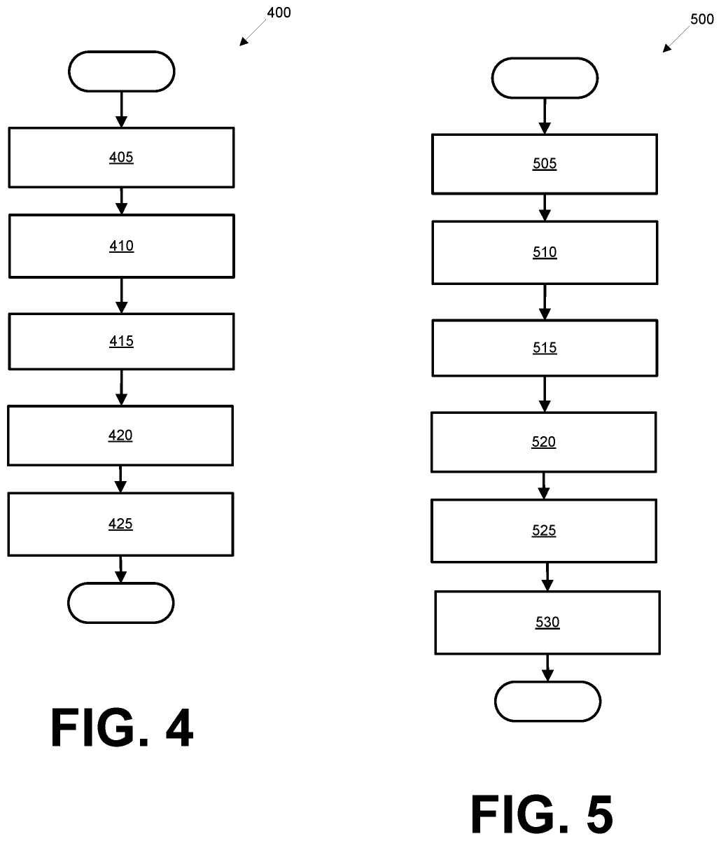

FIG. 4 is a flowchart of an example process 400 for benchmarking driving operations within a simulated driving environment during a prescriptive mode of operation according to the techniques described herein. Blocks of the process 400 can be executed by the server 145. The process 400 begins at block 405 in which one or more simulated driving conditions are generated. The simulated driving conditions can be based on the measure M. As discussed above, the measure M can be used to characterize a given driving condition, e.g., situation.

At block 410, a challenge rating for each driving situation is calculated. At block 415, the autonomous vehicle algorithm is instantiated and provided generated sensor data indicative of the one or more simulated driving conditions. At block 420, score representing the performance of the autonomous vehicle algorithm is assessed and/or stored. At block 425, the metrics representing the performance of the autonomous vehicle algorithm are compared with metrics representing the performance of a human driver. The process 400 then ends.

FIG. 5 is a flowchart of an example process 500 for benchmarking driving operations within a simulated driving environment during a descriptive mode of operation according to the techniques described herein. As described above, the driving challenge ratings are determined prior to the performance evaluation of autonomous vehicle in the simulated driving situations during the prescriptive mode of operation, and the driving challenge ratings are determined contemporaneously with the performance evaluation of autonomous vehicle during the descriptive mode of operation.

Blocks of the process 500 can be executed by the server 145. The process 500 begins at block 505 in which one or more simulated driving conditions are generated.

At block 510, the autonomous vehicle algorithm is instantiated and provided generated sensor data indicative of the one or more simulated driving conditions. At block 515, scores representing the performance of the autonomous vehicle algorithm are assessed and/or stored. At block 520, the driving challenge ratings are assessed for each generated driving situations based on the simulated vehicle activity. At block 525, the score representing the performance of the autonomous vehicle algorithm are compared with score representing the performance of a human driver. The driving challenge ratings for the autonomous vehicle algorithm and the driving challenge ratings for the human driver can be compared. At block 530, one or more profiles are generated based on the comparison of the autonomous vehicle scores and the human driving scores and/or a comparison of the driving challenge ratings. The process 500 then ends.

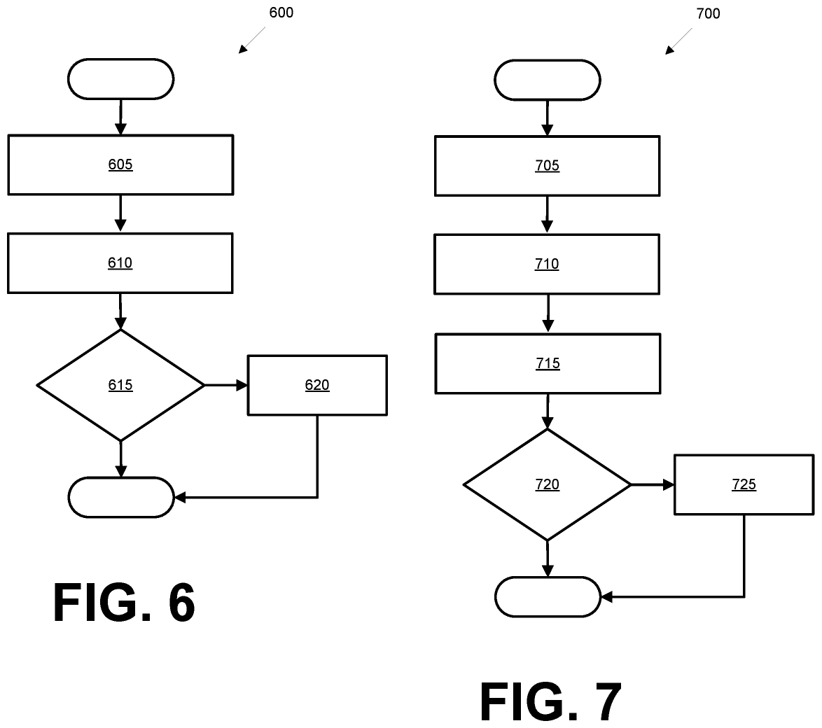

FIG. 6 is a flowchart of an example process 600 for determining whether to generate a driver takeover recommendation according to the techniques described herein. Blocks of the process 600 can be executed by the computer 110. The process 600 begins at block 605 in which the challenge rating based on the defined measure M is determined using the sensor data received from the sensors 115.

At block 610, the calculated challenge rating is compared to the stored challenge ratings for the autonomous vehicle driving algorithm being used by the vehicle 105. The stored challenge ratings indicate a range of driving situations that can be handled by the autonomous vehicle algorithm deployed on the vehicle 105. At block 615, a determination is made whether the calculated challenge rating in block 605 exceeds the range of stored challenge ratings. If yes, a driver takeover recommendation is generated at block 620. Otherwise, the process 600 ends.

FIG. 7 is a flowchart of an example process 700 for detecting a presence of a fault according to the techniques described herein. Blocks of the process 700 can be executed by the computer 110. The process 700 begins at block 705 in which the challenge rating based on defined measure M is determined based on sensor data received from the sensors 115.

At block 710, the performance of the autonomous vehicle driving algorithm is assessed. At block 715, the performance assessment score is compared with the stored performance score of the autonomous vehicle algorithm in the calculated challenge rating.

At block 720, a determination is made whether the performance is less than expected performance for that challenge rating that can be indicative of the presence of a fault. If yes, the data is logged at block 725. In some implementations, the data is transmitted to the vehicle 105 manufacturer. In some implementations, the computer 110 generates an alert to indicate that a dealership visit is recommended due to the presence of a fault. Otherwise, the process 700 ends.

The description of the present disclosure is merely exemplary in nature and variations that do not depart from the gist of the present disclosure are intended to be within the scope of the present disclosure. Such variations are not to be regarded as a departure from the spirit and scope of the present disclosure.

In general, the computing systems and/or devices described may employ any of a number of computer operating systems, including, but by no means limited to, versions and/or varieties of the Microsoft Automotive® operating system, the Microsoft Windows® operating system, the Unix operating system (e.g., the Solaris® operating system distributed by Oracle Corporation of Redwood Shores, California), the AIX UNIX operating system distributed by International Business Machines of Armonk, New York, the Linux operating system, the Mac OSX and iOS operating systems distributed by Apple Inc. of Cupertino, California, the BlackBerry OS distributed by Blackberry, Ltd. of Waterloo, Canada, and the Android operating system developed by Google, Inc. and the Open Handset Alliance, or the QNX® CAR Platform for Infotainment offered by QNX Software Systems. Examples of computing devices include, without limitation, an on-board vehicle computer, a computer workstation, a server, a desktop, notebook, laptop, or handheld computer, or some other computing system and/or device.

Computers and computing devices generally include computer executable instructions, where the instructions may be executable by one or more computing devices such as those listed above. Computer executable instructions may be compiled or interpreted from computer programs created using a variety of programming languages and/or technologies, including, without limitation, and either alone or in combination, Java™, C, C++, Matlab, Simulink, Stateflow, Visual Basic, Java Script, Perl, HTML, etc. Some of these applications may be compiled and executed on a virtual machine, such as the Java Virtual Machine, the Dalvik virtual machine, or the like. In general, a processor (e.g., a microprocessor) receives instructions, e.g., from a memory, a computer readable medium, etc., and executes these instructions, thereby performing one or more processes, including one or more of the processes described herein. Such instructions and other data may be stored and transmitted using a variety of computer readable media. A file in a computing device is generally a collection of data stored on a computer readable medium, such as a storage medium, a random-access memory, etc.

Memory may include a computer readable medium (also referred to as a processor readable medium) that includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random-access memory (DRAM), which typically constitutes a main memory. Such instructions may be transmitted by one or more transmission media, including coaxial cables, copper wire and fiber optics, including the wires that comprise a system bus coupled to a processor of an ECU. Common forms of computer readable media include, for example, a floppy disk, a flexible disk, hard disk, magnetic tape, any other magnetic medium, a CD ROM, DVD, any other optical medium, punch cards, paper tape, any other physical medium with patterns of holes, a RAM, a PROM, an EPROM, a FLASH EEPROM, any other memory chip or cartridge, or any other medium from which a computer can read.

Databases, data repositories or other data stores described herein may include various kinds of mechanisms for storing, accessing, and retrieving various kinds of data, including a hierarchical database, a set of files in a file system, an application database in a proprietary format, a relational database management system (RDBMS), etc. Each such data store is generally included within a computing device employing a computer operating system such as one of those mentioned above, and are accessed via a network in any one or more of a variety of manners. A file system may be accessible from a computer operating system, and may include files stored in various formats. An RDBMS generally employs the Structured Query Language (SQL) in addition to a language for creating, storing, editing, and executing stored procedures, such as the PL/SQL language mentioned above.

In some examples, system elements may be implemented as computer readable instructions (e.g., software) on one or more computing devices (e.g., servers, personal computers, etc.), stored on computer readable media associated therewith (e.g., disks, memories, etc.). A computer program product may comprise such instructions stored on computer readable media for carrying out the functions described herein.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

With regard to the media, processes, systems, methods, heuristics, etc. described herein, it should be understood that, although the steps of such processes, etc. have been described as occurring according to a certain ordered sequence, such processes may be practiced with the described steps performed in an order other than the order described herein. It further should be understood that certain steps may be performed simultaneously, that other steps may be added, or that certain steps described herein may be omitted. In other words, the descriptions of processes herein are provided for the purpose of illustrating certain implementations, and should in no way be construed so as to limit the claims.

Accordingly, it is to be understood that the above description is intended to be illustrative and not restrictive. Many implementations and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future implementations. In sum, it should be understood that the invention is capable of modification and variation and is limited only by the following claims.

All terms used in the claims are intended to be given their plain and ordinary meanings as understood by those skilled in the art unless an explicit indication to the contrary in made herein. In particular, use of the singular articles such as “a,” “the,” “said,” etc. should be read to recite one or more of the indicated elements unless a claim recites an explicit limitation to the contrary.

What is claimed is:

1. A system comprising a computer including a processor and a memory, the memory including instructions such that the processor is programmed to:
execute an autonomous vehicle algorithm simulating vehicle operations within a simulated environment, the simulated environment representing a plurality of driving situations;
determine a challenge rating corresponding to the simulated environment;
determine an autonomous vehicle performance assessment score corresponding to the simulated environment;
compare the autonomous vehicle performance assessment score with a human driving score corresponding to the simulated environment; and
generate a plurality of performance profiles based on the comparison.

2. The system of claim 1, wherein the processor is further programmed to generate the simulated environment based on a measure M, wherein the measure M comprises a set of varying conditions for a driving scenario under which autonomous vehicle driving performance is evaluated.

3. The system of claim 2, wherein the measure M is based on at least one of a complexity of a driving situation, a congestion of a driving situation, or chaos of a driving situation.

4. The system of claim 3, wherein the complexity of the driving situation represents a number of multiple lane changes that are to occur within a defined roadway segment.

5. The system of claim 3, wherein the congestion of the driving situation represents other vehicles traveling at a relatively lower rate of speed with respect to a posted speed limit.

6. The system of claim 3, wherein the chaos of the driving situation represents a number of lane changes by other vehicles proximate to an ego-vehicle.

7. The system of claim 1, wherein the processor is further programmed to generate simulated sensor data representing the simulated environment.

8. The system of claim 1, wherein the processor is further programmed to determine a challenge rating for each generated driving situation within the simulated environment.

9. The system of claim 8, wherein the processor is further programmed to determine the challenge rating for each generated driving situation within the simulated environment during a descriptive mode of operation.

10. The system of claim 8, wherein the processor is further programmed to determine the challenge rating for each generated driving situation within the simulated environment during a prescriptive mode of operation.

11. A method comprising:
executing an autonomous vehicle algorithm simulating vehicle operations within a simulated environment, the simulated environment representing a plurality of driving situations;
determining a challenge rating corresponding to the simulated environment;
determining an autonomous vehicle performance assessment score corresponding to the simulated environment;
comparing the autonomous vehicle assessment score with a human driving score corresponding to the simulated environment; and
generating a plurality of performance profile based on the comparison.

12. The method of claim 11, further comprising generating the simulated environment based on a measure M, wherein the measure M comprises a set of varying conditions for a driving scenario under which autonomous vehicle driving performance is evaluated.

13. The method of claim 12, wherein the measure M is based on at least one of a complexity of a driving situation, a congestion of a driving situation, or chaos of a driving situation.

14. The method of claim 13, wherein the complexity of the driving situation represents a number of multiple lane changes that are to occur within a defined roadway segment.

15. The method of claim 13, wherein the congestion of the driving situation represents other vehicles traveling at a relatively lower rate of speed with respect to a posted speed limit.

16. The method of claim 13, wherein the chaos of the driving situation represents a number of lane changes by other vehicles proximate to an ego-vehicle.

17. The method of claim 11, the method further comprising generating simulated sensor data representing the simulated environment.

18. The method of claim 11, the method further comprising determining a challenge rating for each generated driving situation within the simulated environment.

19. The method of claim 18, the method further comprising determining the challenge rating for each generated driving situation within the simulated environment during at least one of a descriptive mode of operation or a prescriptive mode of operation.

20. A vehicle comprising a computer including a processor and a memory, the memory including instructions such that the processor is programmed to:
determine a challenge rating based on a defined measure M using sensor data from one or more sensors; and
generate at least one of a driver takeover recommendation or an alert indicating a presence of a fault based on a comparison of vehicle performance with the challenge rating.
